(19) United States
(12) Patent Application Publication
(10) Pub. No.: US 2002/0009908 A1
(43) Pub. Date: Jan. 24, 2002

(54) Wire-to-board connector

(76) Inventors: Ta-Wei Liu, Taipei (TW); San-Chi Ho, Yunghe City (TW)

Correspondence Address: RABIN & CHAMPAGNE, PC, 1101 14TH STREET, NW, SUITE 500, WASHINGTON, DC, 20005, US

(21) Appl. No.: 09/793,610

(22) Filed: Feb. 27, 2001

(30) Foreign Application Priority Data
Jul. 20, 2000 (TW) 89212577

(51) Int. Cl. H05K 1/00

(52) U.S. Cl. 439/83

(57) ABSTRACT

A wire-to-board connector achieves the objective of connection and fixation of the wire to the printed circuit board via the electrical conductivity and elastic recovery of the spring.

### BACKGROUND OF THE INVENTION

This application incorporates by reference Taiwanese application Serial No. 089212577, Filed Jul. 20, 2000.

1. Field of the Invention

The invention relates in general to a wire-to-board connector, and more particularly to the wire-to-board connector used in hand-held electronic devices.

2. Description of the Related Art

With the rapid evolution of high technology, electronic products are being developed quickly. A trend of this development is towards portability. Portable electronic products can help people dealing with personal information and daily work, and allows the user to control what, when, where, and how he or she receives and manipulates information due to a great diversity of function thereof. Hence, portable electronic products, such as Personal Digital Assistants (PDA), have proven useful and quite popular.

In order to minimize the size and weight of hand-held electronic products, the appearance of portable devices trend towards smaller, lighter, and easy to carry. However, certain technical limitations still need to be overcome, one of which is the space restriction of printed circuit board occupied with complicate connectors. Therefore, research to minimize the size of interior components of hand-held products so as to develop smaller products is an ongoing challenge.

Referring to FIG. 1 (prior art), the conventional connector, which connects the wire 100 to the printed circuit board 102, consists of the plug 104 and the socket 106, of which the socket 106 is fixed on the printed circuit board 102. One end of the wire 100 is connected to the pin assembly 108 installed in the plug 104. When plug 104 is connected with the socket 106, the pin assembly 108 is joined with the corresponding hole assembly 110 and thus closing the circuit. The completed connector is as shown in FIG. 2 (prior art). However, space as demanded by the conventional wire-to-board connector described above makes minimization difficult.

### SUMMARY OF THE INVENTION

It is therefore an object of the invention to provide an improved and simplified wire-to-board connector. This simplified connector can effectively couple the wire to the printed circuit board while only occupying a very small space thus achieving minimization of space in hand-held products.

According to the objective of the invention, a wire-to-board connector is provided for connecting the wire to the printed circuit board. The characteristic of the wire-to-board connector in the invention includes a spring, which is welded and coupled on the printed circuit board. This wire-to-board connector achieves the electric connection and fixed condition via the electrical conductivity and elasticity of a spring.

### BRIEF DESCRIPTION OF THE DRAWINGS

Other objects, features, and advantages of the invention will become apparent from the following detailed description of the preferred but non-limiting embodiments. The description is made with reference to the accompanying drawings in which:

FIG. 1 (prior art) illustrates the structure of the conventional wire-to-board connector;

FIG. 2 (prior art) is a lateral view of the conventional wire-to-board connector;

FIG. 3 is a perspective view of the wire-to-board connector according to the invention; and

FIG. 4 is a lateral view of the wire-to-board connector according to the invention.

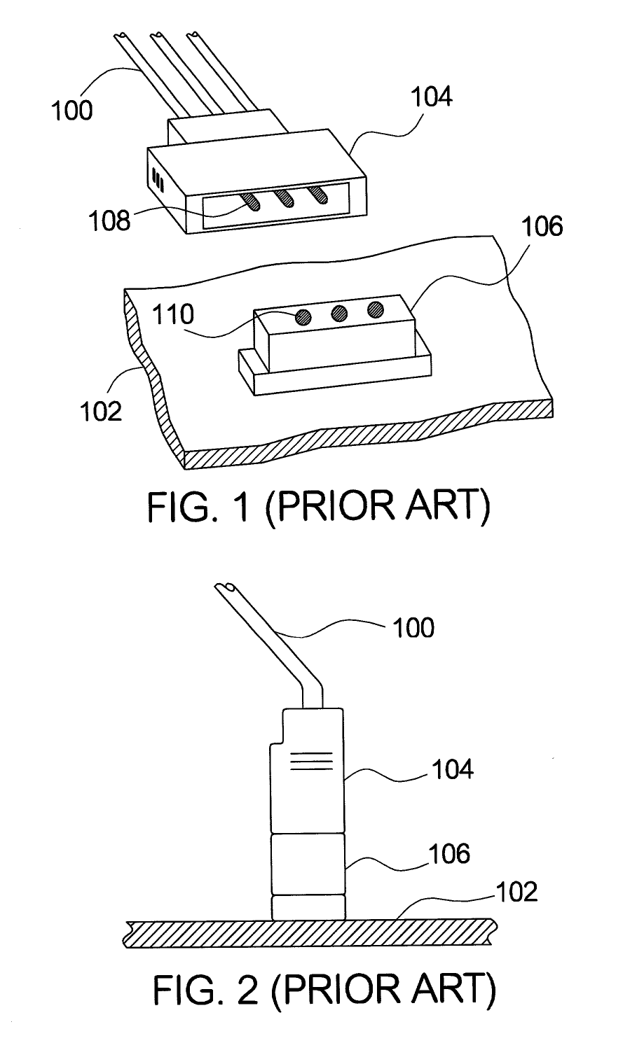

### DESCRIPTION OF THE PREFERRED EMBODIMENT

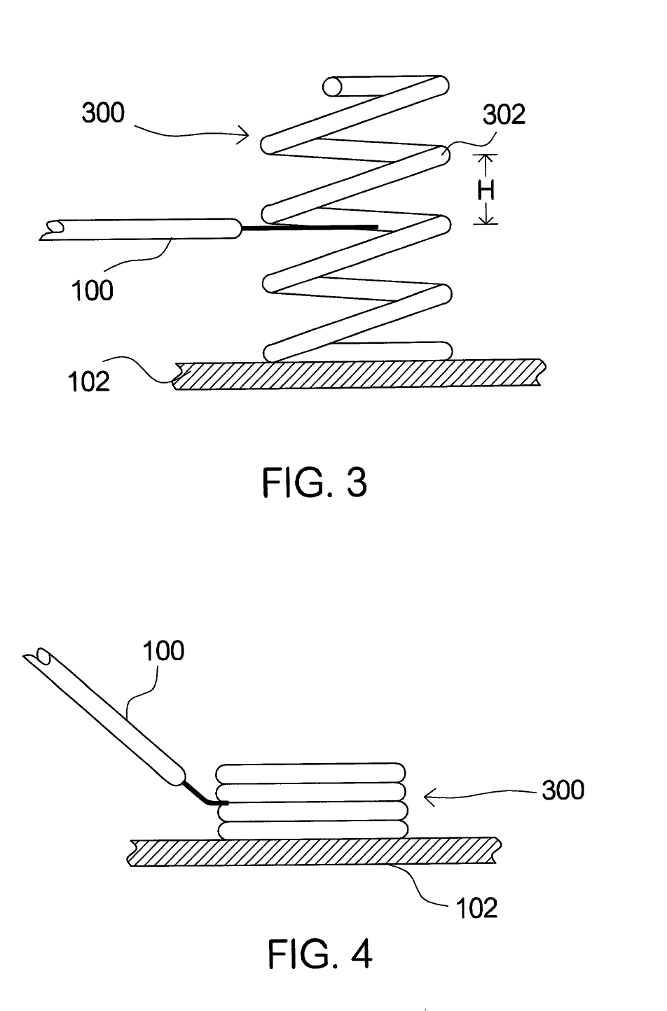

Referring to FIG. 3, which depicts a perspective view of the wire-to-board connector according to the invention, the wire-to-board connector is able to achieve a closed circuit due to the electrical conductivity of the spring 300. The spring 300 is preferrably welded on the print circuit board 102 by the Surface Mounting Technique (SMT). The groove distance H of the spring is such that it is larger than the diameter of the wire 100 that is inserted in the groove when an external force is imposed on the spring 300. Subsequently, the spring 300 compresses and grips the wire 100 tightly by the elastic recovery of the spring 300, as shown in FIG. 4. A live electrical connection between the wire 100 and the printed circuit board 102 is then achieved through the spring 300 because of its electrical conductivity. For example, one end of the wire 100 can link to a power source, speaker, microphone, or earphone (not presented in FIG. 4). Consequently, the invention of the wire-to-board connector achieves the objective of wire-to-board connection utilizing very simple structure and small space.

Furthermore, the invention of the wire-to-board connector provides a preferred method of assemblage. The wire 100 is directly placed in the spring 300 without additional components such as the plug 104 and the socket 106 resulting in a reduction of product assembling time.

According to the invention of the wire-to-board connector, the advantages include very simple structure and minimal required space as well as greatly reducing the time of assembly and overall minimizing the size of hand-held products.

While the invention has been described by way of example and in terms of the preferred embodiment, it is to be understood that the invention is not limited to the disclosed embodiment. To the contrary, it is intended to cover various modifications and similar arrangements and procedures, and the scope of the appended claims therefore should be accorded the broadest interpretation so as to encompass all such modifications and similar arrangements and procedures.

What is claimed is:

1. A wire-to-board connector, comprising:
a wire;
a printed circuit board; and
a spring, wherein the spring is fixed and coupled on the printed circuit board.

2. The wire-to-board connector according to claim 1, wherein the spring is fixed on the printed circuit board through a welding method.

3. The wire-to-board connector according to claim 1, wherein the spring grips the wire tightly with an elastic recovery resulting in an electrical connection between the wire and the printed circuit board.

4. The wire-to-board connector according to claim 3, wherein a groove distance of the spring is larger than a diameter of the wire when an external force is imposed on the spring.

5. The wire-to-board connector according to claim 1, wherein the wire is a metal.

6. The wire-to-board connector according to claim 5, wherein the wire is a electricity-conducting metal and achieves an electrical connection with a printed circuit board due to the electrical conductivity of the metal.
